(19) United States
(12) Patent Application Publication
(10) Pub. No.: US 2026/0142120 A1
(43) Pub. Date: May 21, 2026

(54) 3D TOMOGRAPHY WITH REDUCED DRIFT ERRORS

(71) Applicant: Carl Zeiss SMT GmbH, Oberkochen (DE)

(72) Inventor: Thomas MAYER, Kolbermoor (DE)

(21) Appl. No.: 19/447,596

(22) Filed: Jan. 13, 2026

Related U.S. Application Data
(63) Continuation of application No. PCT/EP2024/070404, filed on Jul. 18, 2024.

(30) Foreign Application Priority Data
Jul. 21, 2023 (DE) 10 2023 206 968.7

(51) Int. Cl. H01J 37/22; H01J 37/304

(52) U.S. Cl. CPC H01J 37/222; H01J 37/3045; H01J 2237/221; H01J 2237/226

(57) ABSTRACT

A method and a dual beam device for three-dimensional volume image generation of semiconductor objects within a wafer can provide higher accuracy. The method and device can be configured to mitigate drifts between a charge-particle beam imaging system and a wafer stage by monitoring displacement vectors and considering the displacement vectors during 3D pixel interpolation from a plurality of two-dimensional cross section images.

### CROSS-REFERENCE TO RELATED APPLICATIONS

The present application is a continuation of, and claims benefit under 35 USC 120 to, international application No. PCT/EP2024/070404, filed Jul. 18, 2024, which claims benefit under 35 USC 119 of German Application No. 10 2023 206 968.7, filed Jul. 21, 2023. The entire disclosure of each of these applications is incorporated by reference herein.

### FIELD

The present disclosure relates to a pattern measurement method of semiconductor objects within a semiconductor wafer. The present disclosure relates to a method, computer program product and a corresponding semiconductor inspection device for performing 3D tomography at a wafer. With the semiconductor inspection device and the method of the disclosure, a drift effect during imaging can be mitigated and a high precision of the three-dimensional image formation can be achieved. The method, computer program product and semiconductor inspection device can be utilized for various inspection tasks, such as quantitative metrology, defect detection, process monitoring, or defect review of integrated circuits within semiconductor wafers.

### BACKGROUND

Semiconductor structures are amongst the finest man-made structures. Semiconductor manufacturing involves precise manipulation, e.g., lithography or etching, of materials such as silicon or oxide at very fine scales in the range of nanometers. A wafer made of a thin slice of silicon serves as the substrate for microelectronic devices containing semiconductor structures built in and upon the wafer. The semiconductor structures are constructed layer by layer using repeated processing steps that involve repeated chemical, mechanical, thermal and optical processes. Dimensions, shapes and placements of the semiconductor structures and patters are subject to several influences. For example, during the manufacturing of 3D-memory devices, the processes include etching and deposition. Other process steps such as the lithography exposure or implantation also can have an impact on the properties of the elements of the integrated circuits. Therefore, fabricated semiconductor structures may suffer from rare and different imperfections. Devices for quantitative metrology, defect-detection or defect review look for these imperfections. These devices are not only used during wafer fabrication. As this fabrication process is relatively complicated and relatively non-linear, optimization of production process parameters can be difficult. As a remedy, an iteration scheme called process window qualification (PWQ) can be applied. In each iteration a test wafer is manufactured based on the currently best process parameters, with different dies of the wafer being exposed to different manufacturing conditions. By detecting and analyzing the test structures with devices for quantitative metrology and defect-detection, the best manufacturing process parameters can be selected. In this way, production process parameters can be tweaked towards optimality. Afterwards, a highly accurate quality control process and device for the metrology semiconductor structures in wafers is used.

Fabricated semiconductor structures are typically fabricated by determined processes and are therefore generally based on prior knowledge. The semiconductor structures are manufactured in a sequence of layers being parallel to a surface of a substrate. For example, in a logic type sample, metal lines are run parallel in metal layers or HAR (high aspect ratio) structures and metal vias run perpendicular to the metal layers. The angle between metal lines in different layers is either 0° or 90°. On the other hand, for VNAND type structures it is known that their cross-sections are circular on average. Furthermore, a semiconductor wafer typically has a diameter of 300 mm and comprises a plurality of several sites, so called dies, each comprising at least one integrated circuit pattern such as for example for a memory chip or for a processor chip. During fabrication, semiconductor wafers run through about 1,000 process steps, and within the semiconductor wafer, about 100 and more parallel layers are formed, comprising the transistor layers, the layers of the middle of the line, and the interconnect layers and, in memory devices, a plurality of 3D arrays of memory cells.

The aspect ratio and the number of layers of integrated circuits is constantly increasing and the structures are growing into third (vertical) dimension. The current height of the memory stacks exceeds a dozen of micrometers. In contrast, the minimum features size is becoming smaller. The minimum feature size or critical dimension is below 10 nanometers (nm), for example 7 nm or 5 nm, and will approach feature sizes about and below 3 nm in near future. While the complexity and dimensions of the semiconductor structures are growing into the third dimension, the lateral dimensions of integrated semiconductor structures are becoming smaller. Therefore, measuring the shape, dimensions and orientation of the features and patterns in three dimensions (3D) and their overlay with high precision can become challenging. The lateral measurement resolution of charged particle systems is typically limited by the sampling raster of individual image points or dwell times per pixel on the sample, and the charged particle beam diameter. The sampling raster resolution can be set within the imaging system and can be adapted to the charged particle beam diameter on the sample. The typical raster resolution is 2 nm or below, but the raster resolution limit can in general be reduced with no physical limitation. The charged particle beam diameter has a limited dimension, which generally depends on the charged particle beam operation conditions and lens. The beam resolution is limited by approximately half of the beam diameter. The lateral resolution can be below 2 nm, for example even below 1 nm.

A common way to generate 3D tomographic data from semiconductor samples on the nm scale is the so-called slice and image approach obtained for example by a dual beam device. A slice- and image approach is described in WO 2020/244795 A1. According to the method of the WO 2020/244795 A1, a 3D volume inspection is obtained at an inspection sample extracted from a semiconductor wafer. In another example, the slice and image method is applied under a slanted angle into the surface of a semiconductor wafer, as described in WO 2021/180600 A1. According to this method, a 3D volume image of an inspection volume is obtained by slicing and imaging a plurality of cross-section surfaces within the inspection 25 volume. For a precise measurement, a large number N of cross-section surfaces in the inspection volume is generated, with the number N exceeding 100 or even more image slices. For example, in a volume with a lateral dimension of 5 μm and a slicing distance of 5 nm, 1,000 slices are milled and imaged. With a typical sample of a plurality of HAR structures with a pitch of for example 70 nm, about 5,000 HAR structures are in one field of view, and a total sum of more than five million cross sections of HAR structures is generated. One exemplary task of semiconductor inspection is to determine a set of specific parameters of semiconductor objects such as high aspect ratio (HAR)—structures inside the inspection volume. Such parameters are for example a dimension, area, a shape, or other measurement parameters.

Generally, semiconductors comprise many repetitive three-dimensional structures. During the manufacturing process or a process development, some selected physical or geometrical parameters of a representative plurality of the three-dimensional structures are measured with relatively high accuracy and relatively high throughput. For monitoring the manufacturing, an inspection volume is defined, comprising the representative plurality the three-dimensional structures. This inspection volume is then analyzed for example by a slice and image approach, leading to a 3D volume image of the inspection volume with high resolution. From the large number of image slices, a three-dimensional volume image is derived with high accuracy. However, the measurement time to generate a 3D volume image can be quite long, and a measurement of a 3D volume image with N=1,000 cross-sections can involve up to 24 hours or even more. During this relatively long measurement time, machine drifts may deteriorate the measurement result and lead to unwanted degradation of the accuracy of the measurement task to be performed.

### SUMMARY

The disclosure seeks to mitigate drift effects during long measurement times of volume inspection task. The disclosure seeks to provide an 3D inspection method configured to generate 3D volume image with relatively high precision even in case of dynamic vibrations or drifts of a wafer inspection system. The disclosure seeks to provide a wafer inspection system configured to execute a method for an improved 3D inspection including a mitigation of drift effects during 3D volume image generation.

According to an embodiment, a method of three-dimensional (3D) volume image acquisition with a dual beam device is disclosed. The method can provide higher accuracy and can be configured to mitigate drifts and dynamic vibrations between a charge-particle beam imaging system and a wafer stage during acquisition of a plurality of two-dimensional cross section images. The method comprises processing, by ion beam milling with a focused ion beam column a plurality of cross-section surfaces C(i=1 . . . N) into a wafer. The method is configured for an ion beam column arranged at an angle GF to a wafer support surface, such that the plurality of cross-section surfaces C(i=1 . . . N) can milled approximately at angle GF to a wafer surface. The method further comprises acquiring a plurality of two-dimensional cross-section images I(i=1 . . . N) with a charge particle beam imaging system arranged at an angle GE to a normal to the wafer support surface. The image acquisition is performed by raster scanning the charge particle imaging beam with a predefined scanning raster. The plurality of two-dimensional cross-section images I(i=1 . . . N) comprises a two-dimensional cross-section image I(n) for each of the cross-section surfaces C(n). The method further comprises obtaining, during acquiring of each of the two-dimensional cross-section images I(i=1 . . . N), a plurality of displacement vectors [dx(p), dy(p)] between a wafer stage and the charge particle beam imaging system, and determining a three-dimensional (3D) volume image from the plurality of two-dimensional cross-section images I(i=1 . . . N) by 3D-pixel interpolation from the plurality two-dimensional images I(i=1 . . . N) with pixel locations of the predefined scanning raster displaced by the plurality of displacement vectors [dx(p), dy(p)]. The plurality of displacement vectors [dx(p), dy(p)] can be obtained for each image pixel with pixel number p of each of the two-dimensional cross-section images. Thereby, a displacement, i.e. an actual exact position of each image pixel within the inspection volume is recorded during image acquisition for later use during three-dimensional volume image generation.

The method incorporating a measurement and recording of the displacement vectors synchronized with the acquisition of pixel values at individual pixel coordinates can help enable a relatively high precision measurement of two-dimensional images and a reconstruction of three-dimensional volume images with a relatively high accuracy. During an image acquisition, drifts or dynamic vibrations can lead to an individual displacement of image pixels. Therefore, for example, an accuracy of a position determination of image features, a determination of a line edge roughness, or a determination of a critical dimension can be deteriorated. The desired accuracy of a measurement can be in the range of few nm, for example 2 nm, 1 nm or even below. For example, a desired overlay of semiconductor features is often about one third of the critical dimension, therefore a measurement accuracy for determination or overlay errors can be below 1 nm, for example 0.5 nm or 0.3 nm. Even methods of active compensation of drifts or dynamic vibrations can be limited in accuracy, and by their limited frequency bandwidth. So, even in presence of active compensation of drifts or dynamic vibrations, a method according to the disclosure can help enable a performance of an inspection task with relatively high precision and relatively high accuracy. For example, a determination of positions of image features, a determination of a line edge roughness, a determination of a critical dimension, a determination of an overlay within three-dimensional volume images can be enabled with an accuracy below 1 nm, for example 0.5 nm or 0.3 nm.

The plurality of displacement vectors [dx(p), dy(p)] for each pixel number p can be obtained with a relatively high precision measuring system, for example with an accuracy below 2 nm, below 1 nm, below 0.5 nm, for example even with an accuracy of 0.1 nm. Thereby, a relatively high precision of a 3D pixel interpolation can be obtained. Thereby, three-dimensional volume images can be obtained with relatively high accuracy even when measurement times for milling and imaging exceed several hours of operation with a dual beam device.

In an example, the method comprises computing of drift image pixel coordinates [XD(p), YD(p)] according to pixel locations [X(p), Y(p)] of the predefined scanning raster displaced by the plurality of displacement vectors [dx(p), dy(p)], determining of a height map Z(x,y) for each cross-section image I(i=1 . . . N); and determining, from the height map Z(x,y), of z-coordinates ZD(p) of each drift compensated lateral pixel coordinate [XD(p), YD(p)]. In an example, the method comprises determining the three-dimensional (3D) volume image by 3D-pixel interpolation from the drift image pixel coordinates [XD(p), YD(p), ZD(p)] of the plurality two-dimensional images I(i=1 . . . N). A 3D-pixel interpolation method is selected from a group of interpolation methods including numerical interpolation, model-based interpolation, and feature matching interpolation using for example CAD data or reference data.

In an example, the method further comprises storing the plurality of displacement vectors [dx(p), dy(p)] synchronized with the storing of pixel values of image pixels of each of the two-dimensional cross-section images I(i=1 . . . N). In an example, the method further comprises a step of analyzing the plurality of displacement vectors [dx(p), dy(p)], a step of generating a correction signal, and a step of providing the correction signal to a compensation element of the imaging charged particle beam system.

In an example, the method further comprises obtaining, during acquiring of each of the two-dimensional cross-section images I(i=1 . . . N), a plurality of measurement results of an environmental influence E(p), and storing of the plurality of measurement results of an environmental influence E(p) synchronized with the storing of pixel values of image pixels of each of the two-dimensional cross-section images I(i=1 . . . N). In an example, the method further comprises computing of an additional displacement of pixel locations [X(p), Y(p)] of the predefined scanning raster according to a function F of an environmental influence E(p). An environmental influence E(p) at each pixel number p can for example be a change of an external electric field, a change of an external magnetic field, an external vibration, a thermal drift during runtime of the dual beam device, or a change of a gravitational field for example due to a change of a moon phase.

In an example, the method further comprises an image registration of each of the two-dimensional cross-section images I(i=1 . . . N) with alignment fiducials or a feature-based image registration. The method may further comprise at least one image improvement method selected from a group of methods including an image distortion compensation, a magnification adjustment, a noise removal, a contrast enhancement, an image normalization, and a thresholding. The method may further comprise at least one object detection method selected from a group of object detection methods including template matching, contour extraction and machine learning object detectors.

With the method, drifts between a wafer stage and a charge particle imaging beam can be monitored and even small displacement vectors can be recorded during image acquisition. According to the disclosure, drifts include any deviations in position and angle between wafer stage and a reference coordinate of the charge particle imaging beam, including rapid or dynamic vibrations with frequencies according to the scanning frequency of the charge particle imaging beam, and slower vibrations during image acquisition of one two-dimensional cross-section image. Drifts further include even slower changes on longer timescales, for example changes of the position and angle between wafer stage and the reference coordinate of the charge particle imaging beam during acquisition of a sequence of many two-dimensional cross-section images.

A dual beam system according to an embodiment comprises a wafer stage for holding a wafer on a wafer support surface and a focused ion beam column, arranged at a first angle GF to the wafer support surface. The dual beam system further comprises a charged particle beam imaging system mounted on a rigid support frame at a second angle GE to a normal to the wafer support surface. The dual beam system according to the embodiment further comprises a high precision sensor for measuring during use a plurality of relative position vectors between the wafer stage and the rigid support frame and a control unit. The control unit is provided with a processing logic and at least one memory for storing a set of software instructions and for at least temporally storing image pixel values obtained by an image sensor according to the pixel locations of a selected scanning raster. The processing logic is configured to execute the set of software instructions to cause the dual beam system to perform any of the methods described above.

In an example, the angle GF is between 10° and 60° and the angle GE is between 0° and 60°. In an example, the angle GE=0° and the charged particle beam imaging system is arranged perpendicular to a wafer support surface. In another example, the focused ion beam column and the charged particle beam imaging system are arranged relative to each other at an angle GFE, wherein the angle GFE=90°.

A dual beam system according to an embodiment comprises a wafer stage for holding a wafer on a wafer support surface, a focused ion beam column at a first angle GF to the wafer support surface and a charged particle beam imaging system mounted on a rigid support frame at a second angle GE to a normal to the wafer support surface. The charged particle beam imaging system is configured for obtaining a plurality of cross-section image slices I(i=1 . . . N). The dual beam system further comprises a control unit with a memory and logic to control an operation of the dual beam system and to temporally store image pixel values obtained by an image sensor according to the pixel locations of a selected scanning raster. The dual beam system further comprises a high precision sensor, connected to the control unit, for measuring during use a plurality of displacement vectors [dx(p), dy(p)] between the wafer stage and the rigid support frame. The control unit is configured to receive and store the plurality of displacement vectors [dx(p), dy(p)] in correspondence with the pixel locations or pixel number p of the selected scanning raster and configured to determine a three-dimensional (3D) volume image by 3D-pixel interpolation, thereby taking the plurality of displacement vectors [dx(p), dy(p)] into account. The control unit is therefore configured for computing of drift image pixel coordinates [XD(p), YD(p)] according to pixel locations [X(p), Y(p)] of the predefined scanning raster displaced by the plurality of displacement vectors [dx(p), dy(p)], and for determining a height map Z(x,y) for each of a plurality of cross-section image slice I(i=1,N). The control unit is therefore configured for determining z-coordinates ZD(p) of each drift compensated lateral pixel coordinate [XD(p), YD(p)], and for determining the three-dimensional (3D) volume image by 3D-pixel interpolation from the drift image pixel coordinates [XD(p), YD(p), ZD(p)] of plurality two-dimensional images I(i=1 . . . N).

According to an embodiment, a method of three-dimensional (3D) volume image acquisition with increased accuracy and reduced measurement time can be provided. The method can be configured for a dual beam device with an ion beam column arranged at a slanted angle GF between 10° and 60° to a wafer support surface. The method comprises processing, by ion beam milling with a focused ion beam column a plurality of cross-section surfaces C(i=1 . . . N) into a wafer, wherein each pair of cross-section surfaces C(i=1 . . . N) is having a milling distance D. The method comprises acquiring, by a charge particle beam imaging system arranged at an angle GE to a normal to the wafer support surface, a plurality of two-dimensional cross-section images I(i=1 . . . N) with a predefined scanning raster with a sampling raster dy unequal to D/sin (GF) in a y-direction, for example dy<D/sin(GF) or dy>D/sin (GF). The plurality of two-dimensional cross-section images I(i=1 . . . N) comprising a two-dimensional cross-section image of each of the cross-section surfaces C(i=1 . . . N). With for example a larger sampling raster dy exceeding D/sin (GF), the sampling raster of the plurality of two-dimensional cross-section images I(i=1 . . . N) does not fit to the regular raster of a three-dimensional volume image in either the y-direction or a direction perpendicular to the wafer surface. The coordinate system is selected that the optical axis of the ion beam column is within the y-z-plane. The method further comprises determining a three-dimensional (3D) volume image from the plurality of two-dimensional cross-section images I(i=1 . . . N) by 3D-pixel interpolation from the plurality two-dimensional images I(i=1 . . . N).

In an example, the method comprises determining a height map Z(x,y;i) for each cross-section image slice I(i=1 . . . N), and determining the three-dimensional (3D) volume image by 3D-pixel interpolation from the image pixel coordinates [X(p), Y(p), Z(X(p), Y(p)] of the plurality two-dimensional images I(i=1 . . . N) with height maps Z(x,y;i). A 3D-pixel interpolation method is for example including a model-based interpolation or feature matching interpolation using CAD data or reference data of semiconductor objects within the wafer.

In an example, the method comprises obtaining, during acquiring of each of the two-dimensional cross-section images I(i=1 . . . N), a plurality of displacement vectors [dx(p), dy(p)] between a wafer stage and the charge particle beam imaging system, and storing the plurality of displacement vectors [dx(p), dy(p)] synchronized with the storing of pixel values of image pixels of each of the two-dimensional cross-section images I(i=1 . . . N). The method may further comprise computing of drift image pixel coordinates [XD(p), YD(p)] according to pixel locations [X(p), Y(p)] of the predefined scanning raster displaced by the plurality of displacement vectors [dx(p), dy(p)], determining of a height map Z(x,y) for each cross-section image I(i=1 . . . N), and determining of z-coordinates ZD(p) of each drift compensated lateral pixel coordinate [XD(p), YD(p)]. A high-precision three-dimensional (3D) volume image is thereby obtained by 3D-pixel interpolation from the drift image pixel coordinates [XD(p), YD(p), ZD(p)] of the plurality of two-dimensional images I(i=1 . . . N).

While examples and embodiments are described at the examples of semiconductor wafers, it is understood that the disclosure is not limited to semiconductor wafers but can for example also be applied to reticles or masks for semiconductor fabrication.

The disclosure described by examples and embodiments is not limited to the embodiments and examples but can be implemented by those skilled in the art by various combinations or modifications thereof. The present disclosure can be more fully understood with reference to the following drawings.

### BRIEF DESCRIPTION OF THE DRAWINGS

FIG. 1 shows an illustration of a wafer inspection or metrology system for 3D volume inspection with a dual beam device.

FIG. 2 is an illustration of a slice- and image method of a volume inspection in a wafer.

FIG. 3 illustrates an example of a cross section image, obtained by the slice-and image method.

FIG. 4 illustrates an example of a perfect sampling raster of two cross section images.

FIG. 5 illustrates an example of a perfect sampling raster of a series of cross section images.

FIG. 6 illustrates a 3D volume pixel interpolation from an ideal sampling raster.

FIG. 7 shows a wafer inspection system according to an embodiment.

FIG. 8 illustrates a method of charge mitigation.

FIGS. 9A-9C illustrate a 3D volume pixel interpolation from a sampling raster under drift.

FIG. 10 illustrates a sampling raster, a synchronized position signal and a drift corrected pixel raster of a digital image.

FIGS. 11A-11B shows a result of an inspection.

### DETAILED DESCRIPTION

Throughout the figures and the description, same reference numbers are used to describe same features or components. The coordinate system is selected that the wafer surface 55 coincides with the XY-plane. In the disclosure, the term drift is used as describing any temporal position displacement on time scales comparable to the scanning frequency of the charged particle imaging beam of for example 80 MHz, corresponding to typical dwell time at each individual pixel location of few ns, for example 12.5 ns, 20 ns, 30 ns or 50 ns.

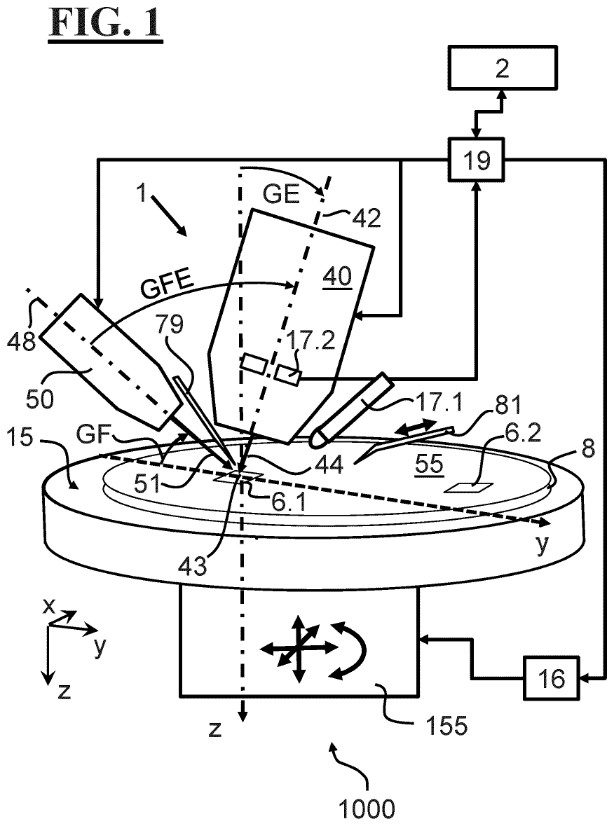

For the investigation of 3D inspection volumes in semiconductor wafers, a slice and imaging method has been proposed, which is applicable to inspection of volumes inside a wafer. In an example, a 3D volume image is generated from an inspection volume inside a wafer by the so called “wedge-cut” approach or wedge-cut geometry, without the need of a removal of a sample piece from the wafer. The slice and image method is applied to an inspection volume with dimensions of few μm, for example with a lateral extension of 5 μm to 10 μm in wafers with diameters of 200 mm or 300 mm. The lateral extension can also be larger and reach up to 30 or 50 micrometers. A V-shaped groove or edge is milled in the top surface of an integrated semiconductor wafer to make accessible a cross-section surface at an angle to the top surface. 3D volume images of inspection volumes are acquired at a limited number of inspection sites, for example representative sites of dies, for example at process control monitors (PCM), or at sites identified by other inspection tools. The slice and image method will destroy the wafer only locally, and other dies may still be used, or the wafer may still be used for further processing. The methods and inspection systems according to the 3D Volume image generation are described in WO 2021/180600 A1, which is fully incorporated herein by reference. An example of a wafer inspection system 1000 for 3D volume inspection is illustrated in FIG. 1. The wafer inspection system 1000 is configured for a slice and imaging method under a wedge cut geometry with a dual beam device 1. For a wafer 8, several inspection sites, comprising inspection sites 6.1 and 6.2, are defined in a location map or inspection list generated from an inspection tool or from design information. The wafer 8 is placed on a wafer support surface 15. The wafer support surface 15 is mounted on a stage 155 with actuators and position control. Actuators and mechanisms for precision control for a wafer stage such as Laser interferometers are known in the art. A control unit 16 is configured to control the wafer stage 155 and to adjust an inspection site 6.1 of the wafer 8 at the intersection point 43 of the dual-beam device 1. The dual beam device 1 comprises a FIB column 50 with a FIB optical axis 48 and a charged particle beam (CPB) imaging system 40 with optical axis 42. The focused ion beam column (50) is arranged at an angle GF to the surface of the wafer support surface 15 of the wafer stage (155). Therefore, during use, the wafer surface 55 is arranged at a slant angle GF to the FIB axis 48. During use, the wafer surface 55 is arranged at the intersection point 43 of both optical axes of FIB and CPB imaging system. FIB axis 48 and CPB imaging system axis 42 include an angle GFE, and the CPB imaging system axis forms an angle GE with the normal to the wafer support surface 15. In the coordinate system of FIG. 1, the normal to the wafer support surface 15 is given by the z-axis. The focused ion beam (FIB) 51 is generated by the FIB-column 50 and is impinging under angle GF on the surface 55 of the wafer 8. Slanted cross-section surfaces are milled into the wafer by ion beam milling at the inspection site 6.1 under approximately the slant angle GF. In the example of FIG. 1, the slant angle GF is approximately 30°. The actual slant angle of the slanted cross-section surface can deviate from the slant angle GF by up to 1° to 4° due to the beam divergency of the focused ion beam, for example a Gallium-Ion beam. The FIB column 50 can for example be a Gallium FIB, or a FIB with a gas field ion source (GFIS) with other kinds of ion species, such as Xenon or Argon ions. With the charged particle beam imaging system 40, inclined under angle GE to the normal to the wafer support surface 15, images of the milled surfaces are acquired. In the example of FIG. 1, the angle GE is about 15°. However, other arrangements are possible as well, for example with GE=GF, such that the CPB imaging system axis 42 is perpendicular to the FIB axis 48, or GE=0°, such that the CPB imaging system axis 42 is perpendicular to the wafer support surface 15.

During imaging, a beam of charged particles 44 is scanned by a scanning unit of the charged particle beam imaging system 40 along a scan path over a cross-section surface of the wafer 8 at inspection site 6.1, and secondary particles as well as scattered particles are generated. For example, secondary electron particle detector 17.1 collects at least some of the secondary particles and scattered particles and communicates the particle count with a control unit 19. Other detectors for other of interaction products may be present as well, for example in-lens detector 17.2 for collection of backscattered charged particles. Control unit 19 is in control of the charged particle beam imaging column 40, of FIB column 50 and connected to a stage control unit 16 to control the position of the wafer 8 mounted on the wafer support surface 15 via the wafer stage 155. Control unit 19 communicates with operation control unit 2, which triggers placement and alignment for example of inspection site 6.1 of the wafer 8 at the intersection point 43 via wafer stage movement and triggers repeatedly operations of FIB milling, image acquisition and stage movements.

Each new intersection surface is milled by the FIB beam 51, and imaged by the charged particle imaging beam 44, which is for example a scanning electron beam or a Helium-Ion-beam of a Helium ion microscope (HIM). In an example, the dual beam system comprises a first focused ion beam system 50 arranged at a first angle GF1 and a second focused ion column arranged at the second angle GF2, and the wafer is rotated between milling at the first angle GF1 and the second angle GF2, while imaging is performed by the imaging charged particle beam column 40, which is for example arranged perpendicular to the wafer surface 55.

The dual beam system 1 further comprises a gas injection system (GIS) 79, with a gas nozzle connected via a valve (not shown) to at least one gas reservoir (not shown). Thereby, controlled amounts of precursor gases can be provided during milling or imaging, and for example metal coatings can be generated. For example, alignment marks or fiducials can be generated. For example, a Tungsten metal coating is generated by providing Tungsten Hexacarbonyl. The metal coating can be shaped by ion beam milling and alignment markers or fiducials are formed in proximity to an inspection site. Thereby, a precise registration and image alignment of the plurality of cross section images is enabled. With dedicated precursor gases, a milling operation by FIB 51 can be enhanced. For example, a homogeneity of a milling operation in compositions of different material can be improved and curtaining can be reduced. Compositions of materials in a semiconductor wafer can comprise Silicon, Silicon Dioxide, Silicon Nitride, Copper, Aluminum, Tungsten or other materials. Examples of precursor gases include at least one of Ammonia, Ammonium Hydroxide, Ammonium Carbamate, Bromine, Chlorine, Hydrazine, Hydrogen Peroxide, Hadacidin, Iodine, di-iodo-ethane, Isopropanol, Methy Difluoroacetate, Nitroethane, Nitroethanol, Nitrogen, Nitrogen Tetroxide, Nitrogen Trifluoride, Nitromethane, Nitropropane, Nitrobutane, Oxygen, Ozone, PMCPS, Tungsten Hexacarbonyl, Water, or Xenon Difluoride. Other gases are, however, are possible as well, for example methoxy acetylchloride, methyl acetate, methyl nitroacetate, ethyl acetate, ethyl nitroacetate, propyl acetate, propyl nitroacetate, nitro ethyl acetate, methyl methoxyacetate, and methoxy acetylchloride, Acetic acid or thiolacetic acid, Hexafluoro-acetylacetone, silazane, trifluoroacetamide, dicobalt octacarbonyl, molybdenum hexacarbonyl, and combinations thereof.

Furthermore, dual beam system 1 further comprises a contact pin 81. Contact pin 81 is connected to a manipulator (not shown) for precise movement of the contact pin 81, for example under control of the charged particle beam 44 during an image acquisition. Thereby, structures present on the wafer surface can be contacted and electrically connected to control device 19.

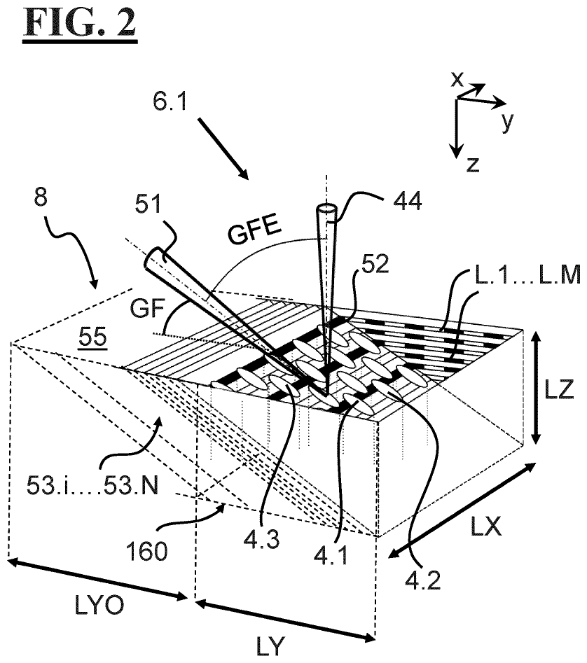

FIG. 2 illustrates the wedge cut geometry at the example of a 3D-memory stack. FIG. 2 illustrates the situation, when the surface 52 is the most recently milled cross-section surface which was milled by FIB 51. The cross-section surface 52 is scanned for example by SEM beam 44, which is in the example of FIG. 2 arranged at normal incidence to the wafer surface 55, and a high-resolution cross-section image slice is generated. The cross-section surfaces 53.1 . . . 53.N are subsequently milled with a FIB beam 51 at an angle GF of approximately 30° to the wafer surface 55, but other angles GF, for example between GF=20° and GF=60° are possible as well. The cross-section image slice comprises first cross-section image features, formed by intersections with high aspect ratio (HAR) structures or vias (for example first cross-section image features of HAR-structures 4.1, 4.2, and 4.3) and second cross-section image features formed by intersections with layers L.1 . . . . L.M, which comprise for example SiO2, SiN- or Tungsten lines. Some of the lines are also called “word-lines”. The maximum number M of layers is typically more than 50, for example more than 100 or even more than 200. The HAR-structures and layers extend throughout most of the volume in the wafer but may comprise gaps. The HAR structures typically have diameters below 100 nm, for example about 80 nm, or for example 40 nm. The cross-section image slices contain therefore first cross-section image features as intersections or cross-sections of the HAR structures at different depth (Z) at the respective XY-location. In case of vertical memory HAR structures of a cylindrical shape, the obtained first cross-sections image features are circular or elliptical structures at various depths determined by the locations of the structures on the sloped cross-section surface 52. The memory stack extends in the Z-direction perpendicular to the wafer surface 55. The thickness d or minimum distances d between two adjacent cross-section image slices is adjusted to values typically in the order of few nm, for example 30 nm, 20 nm, 10 nm, 5 nm, 4 nm or even less. Once a layer of material of predetermined thickness d is removed with FIB, a next cross-section surface 53.i . . . 53.N is exposed and accessible for imaging with the charged particle imaging beam 44. During repeated milling and imaging, a plurality of cross sections is formed, and a plurality of cross section images are obtained, such that an inspection volume of size LX×LY×LZ is properly sampled and for example a 3D volume image can be generated. Thereby, the damage to the wafer is limited to the inspection volume 160 plus a damaged volume in y-direction of length LYO. With an inspection depth LZ about 10 μm, the additional damage volume in y-direction is typically limited to below 20 μm.

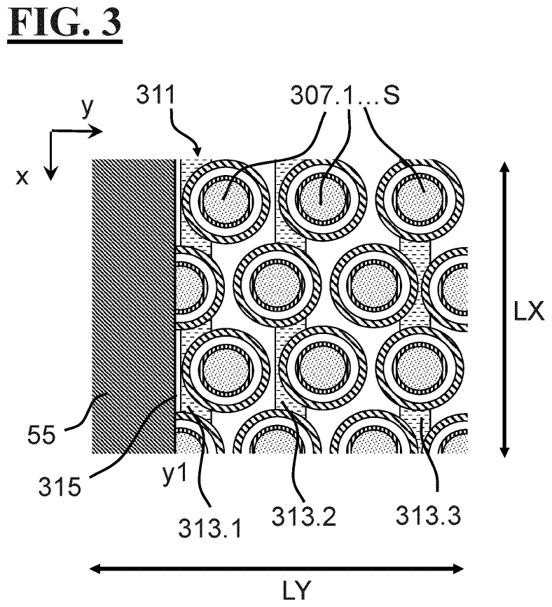

FIG. 3 shows an example of a cross-section image slice 311 generated by the imaging charged particle beam 44, corresponding to the cross-section surface 52. The cross-section image slice 311 comprises an edge line 315 between the slanted cross-section and the surface 55 of the wafer at the edge coordinate y1. Right to the edge, the image slice 311 shows several cross-sections 307.1 . . . 307.S through the HAR structures which are intersected by the cross-section surface 52. In addition, the image slice 311 comprises cross-sections of several word lines 313.1 to 313.3 at different depths or z-positions.

Each digital image of each cross-section surface comprises first cross-section features of HAR channels and second cross-section features of word lines at different depths. The depth of the word lines 313.1 to 313.3 is constant over large areas of a wafer. In an example, the word lines 313.1 to 313.3 are used as reference for a determination of the depth coordinate of a cross-section image slice 311. With the word lines 313.1 to 313.3, a depth map Z(x,y) of the slanted cross-section surface 52 can be generated. In another example, the distance to the edge line 315 is used for computation of the depth map Z(x,y). Thereby, for each pixel with transversal coordinates [x,y] according to the scanning operation of the charged particle imaging system 40, a depth coordinate according to the depth map Z(x,y) can be computed and high precision volume measurements are possible with the slice- and image-method in wedge-cut geometry. Examples and further details of image registration and depth map computation are provided in WO 2021/180600 A1, cited above and incorporated herein by reference.

Further, after performing a segmentation and annotation of a cross-section image of a semiconductor object of interest, HAR channel cross sections are identified and properties of HAR channel cross sections are determined by machine learning methods. Examples are described in WO 2022/223229A1 and PCT/EP2022/082590, which are hereby incorporated by reference

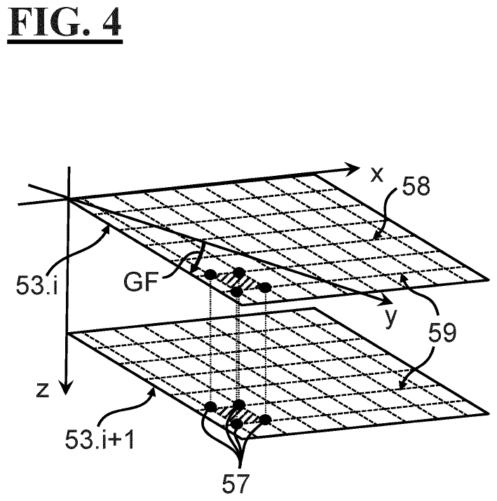

FIG. 4 illustrates the pixel grid generated by the slice-and-image method. Two examples of cross section surfaces 53.i and 53.i+1 are shown, both milled by FIB at milling angle GF, After milling, each cross section surface 53.i and 53.i+1 is raster scanned by charged particle imaging beam 44. The electron beam is scanned along scanning lines 59 in x-direction and after each scanning line, the electron beam is scanning deflected to the next scanning line in y-direction. Thereby, a digital image of each cross-section surface 53 with cartesian raster 58 is obtained. Ideally, the dwell points 57, corresponding to the 2D image pixels, are at same lateral x-y-coordinates for each cross-section surface. The depth coordinates in z-direction are given according to the depth maps Z(x,y) of each cross section image slice.

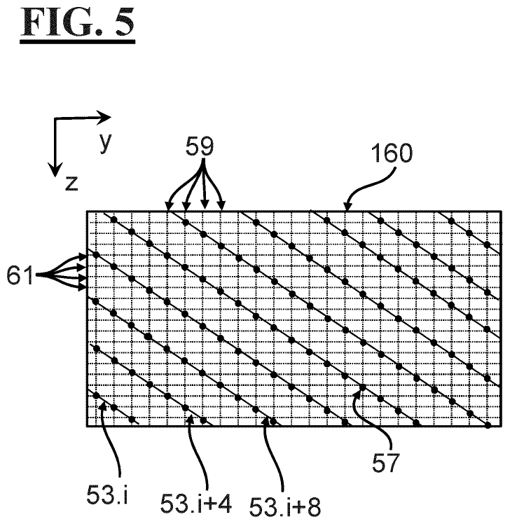

FIG. 5 shows a cross section in y-z plane through a 3D volume image, generated from inspection volume 160. The image sampling points 57 are within the cross-section surfaces 53. The 3D volume image comprises a plurality of virtual image slices 61 normal to the z-axis, and a plurality of scanning line columns 59. Sampling points 57 located at cross-sections 53. Only every fourth cross-section surface 53.i, 53.i+4, 53.i+8, . . . is shown. To achieve a regular volume grid from the 2D sampling or scanning raster 58 on the plurality of tilted cross section surfaces, milling thickness D is selected according to condition D=dy*sin (GF), with dy: sampling raster spacing in y-direction; D: milling thickness between to cross section surfaces (perpendicular to cross section surfaces); GF: tilt angle of milling beam.

In analogy, a sampling raster spacing in y-direction can be selected by the equation for a given milling thickness.

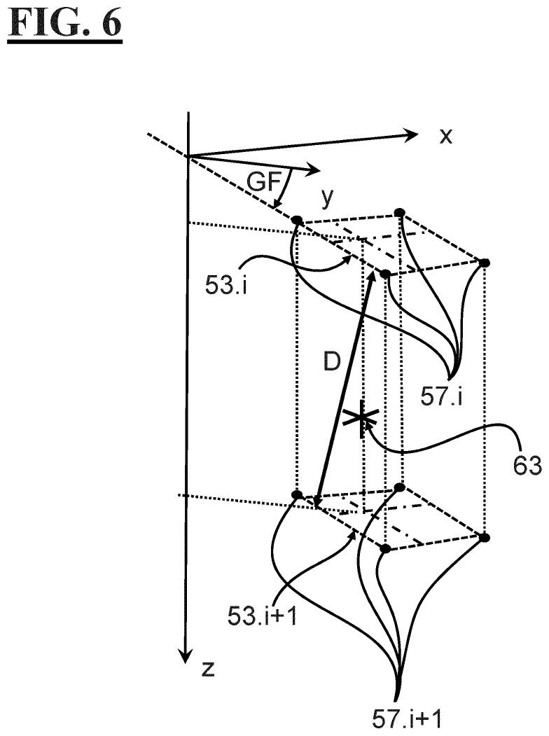

According to an embodiment, optionally, further virtual cross section or virtual images slices 61 can be computed between the sampling points 57 by interpolation. For example, is the milling distance D is increased, such that the z-sampling of the 3D-volume is not in correspondence to the lateral image sampling. In such an example, the regular 3D volume grid does not correspond to the raster spacing of the plurality of 2D-scanning raster 58 on the plurality of cross-section surfaces 53 (see FIG. 4). In such examples, pixel values of the three-dimensional volume image are obtained via interpolation. An example is shown in FIG. 6. Pixel value of 3D volume pixel 63 is computed from surrounding sampling points 57.i and 57.i+1 from cross sections 53.1 and adjacent cross-section 53.i+1 at distance D. During interpolation, the tilt angle GF of cross sections 53.i and 53.i+1 or the different z-coordinates or depths of the image pixels are taken into account. According to an embodiment, a method of three-dimensional (3D) volume image acquisition with a dual beam device (1) is therefore comprising a step of processing, by ion beam milling with a focused ion beam column (50) arranged at a slanted angle GF between 10° and 60° to a wafer support surface (15), a plurality of cross-section surfaces (C(i), 52, 53) in a wafer (8), each pair of cross-section surfaces (C(i), 52, 53) having a milling distance D. The method of three-dimensional (3D) volume image acquisition further comprises a step of acquiring, by a charge particle beam imaging system (40) arranged at an angle GE to a normal to the wafer support surface (15), a plurality of two-dimensional cross-section images (I(i), 311) with a predefined scanning raster (58) with a sampling raster dy. According to the embodiment, sampling raster dy and milling thickness are selected such that dy is unequal to D/sin (GF). The method of three-dimensional (3D) volume image acquisition with a dual beam device (1) is therefore comprising a step to determine a three-dimensional (3D) volume image on a regular raster grid from the plurality of two-dimensional cross-section images (I(i=1 . . . N), 311) by pixel interpolation from the plurality two-dimensional images (I(i=1 . . . N), 311).

During performing the plurality of milling operations by FIB 50 and image acquisitions by imaging charged particle beam system 40, the dual beam device 1 is subject to drift and other disturbances. Consequently, pixel values of the pixels 57 are not representing the correct values corresponding to the object of interest at the nominal or ideal pixel position, and a measurement result is deteriorated by drift and other disturbances.

According to an embodiment of the disclosure, an improved wafer inspection system configured for milling and image acquisition of a plurality of cross section surfaces with reduced impact of drift effects is provided. The improved wafer inspection system is configured for performing a sequence of milling and image acquisitions of a plurality of cross section surfaces, comprises the steps of
generating by ion-beam milling, into an inspection volume 160 of a wafer 8, a plurality of cross-section surfaces 53,
scanning, by an electron beam 44, at least segments of each cross-section surface 53 with primary electrons,
monitoring, during image acquisition, a plurality of drift vectors between a wafer stage 15 and the imaging charged-particle beam system 40,
writing the plurality of drift vectors of at least a plurality of representative dwell points into a memory, and
compensating the drift by 3D-volume interpolation under consideration of the plurality of drift vectors of the plurality of dwell points.

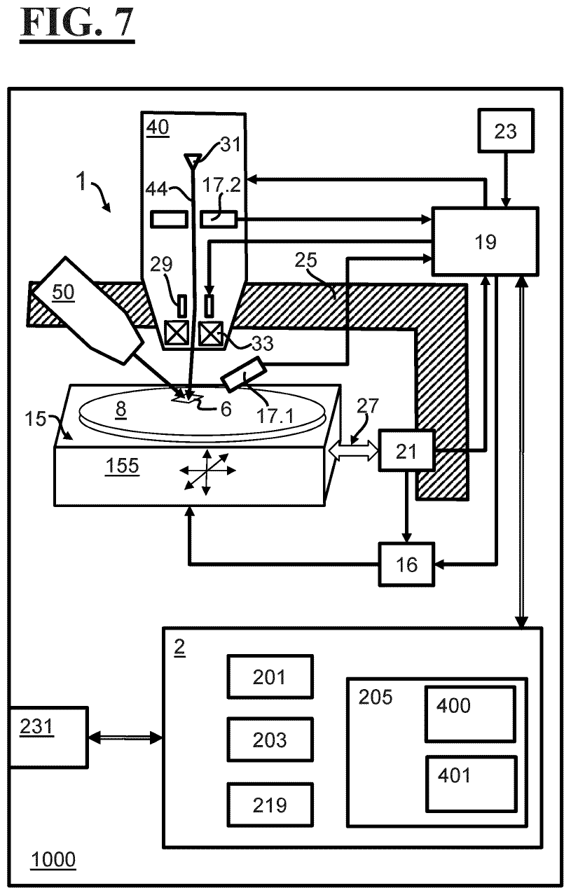

An example of an improved wafer inspection system is illustrated in FIG. 7. The wafer inspection system 1000 comprises a dual beam system 1. A dual beam system is illustrated in FIG. 1 and reference is also made to the description of FIG. 1. Certain features of a dual beam system 1 are a first charged particle or FIB column 50 for milling and a second, charged particle beam imaging system 40 for high-resolution imaging of cross section surfaces. A dual beam system 1 comprises at least one detector 17 for detecting secondary particles, which can be electrons or photons. In the example, a first detector 17.1 is arranged close to the interaction volume of the primary beam 44 with the wafer 8 and configured to attract and collect secondary electrons. A second, in-lens detector 17.2 is arranged within the imaging charged particle beam system 40 and configured to collect backscattered electrons. A dual beam system 1 further comprises a wafer stage 155 configured for holding during use a wafer 8. The wafer stage 155 comprises actuators for lateral and axial displacement or rotation of the wafer stage 155. For example, a wafer stage comprises long stroke actuators for displacements of the wafer 8 from a first inspection site 6.1 to a second inspection site 6.2 (see FIG. 1) and short stroke actuators of high precision for precision adjustment of the wafer 8 at an inspection position. The degrees of freedom for position adjustment and movement of the wafer stage 155 can be between three (x,y, rotation around z-axis) and all six degrees of freedom. The dual beam system 1 further comprises a control unit 19. The control unit 19 is configured with memory and logic to control operation of the dual beam system 1 and to temporally store image pixel values obtained by image sensors 17.1 and 17.2 according to the pixel locations of a selected scanning raster 58 (see FIG. 4).

The wafer stage 155 is position controlled by a stage control unit 16, which is connected to a high precision position sensor 21 configured for measuring during use the position of the wafer stage 155 relative to the charged particle beam imaging system 40 in at least two degrees of freedom (x,y). In an example, the charged particle beam imaging system 40 and the high precision position sensor 21 are mounted on a rigid support or metrology frame 25, which acts as a reference for the relative position measurement between wafer stage 155 and charged particle imaging beam 44.

Examples of precision position sensor 21 comprise Laser interferometers, grid interferometers, capacitive sensors or confocal sensors. Precision position sensor 21 is configured for performing during use at least one position measurement 27 of the position of the wafer stage 155 with respect to the metrology frame 25. Precision position sensor 21 is further connected to control unit 19 and configured to provide during image acquisition a plurality of relative position vectors of stage 15 for a plurality of representative dwell points. Generally, the control unit (19) is configured to receive and store a plurality of relative position vectors in correspondence with pixel locations of a selected scanning raster (58). In an example, a position vector is received and stored in a memory together with each image pixel value received from detector 17 for each image pixel with number p. In an example, a position vector is received and stored in a memory together with each for example 10th image pixel value received from detector 17 for each 10th image pixel. Position vectors in between can for example be obtained via interpolation between two subsequent position vectors. Since the reference coordinate system for position vectors can be selected arbitrarily, for example coincident with the interception point of the optical axes of the two charged particle beam systems, a position vector is analogue to a displacement vector.

During use, charged particle beam source 31 generates charged particles. The dual beam system 1 further comprises a deflection scanner 29 for raster scanning the charged particle imaging beam 40. The dual beam system 1 further comprises an objective lens 33 for focusing the charged particle imaging beam 40 onto a cross-section surface 53. Deflection scanner 29 and objective lens 33 are connected and controlled by control unit 19.

The dual beam system 1 of the example illustrated in FIG. 7 further comprises a condition monitor 23, which is configured as a measurement system for measurements of environmental influences during the image acquisition in correspondence with pixel locations of the selected scanning raster (58). Condition monitor 23 comprise at least one of a group of measurement systems including an electromagnetic field sensor, a vibration sensor, a temperature sensor, a gravitation sensor. Condition monitor 23 is connected to control unit 19 and configured to provide during image acquisition a plurality of measurements of environmental influences during images scanning at a plurality of representative dwell points. In an example, a position vector is received and stored in a memory together with each image pixel value received from detector 17 for each image pixel. In an example, a measurement of an environmental influence is received and stored in a memory together with each for example 10^{th} image pixel value received from detector 17 for each 10^{th} image pixel.

The wafer inspection system 1000 further comprises an operation control unit 2. The operation control unit 2 comprises at least one processing engine 201, which can be formed by multiple parallel processors including GPU processors and a common, unified memory. The operation control unit 2 further comprises an SSD memory or disk memory or storage 203 for storing data, for example including training data and a trained machine learning algorithm, and a plurality of cross-section images. The operation control unit 2 further comprises a user interface 205, comprising the user interface display 400 and user command devices 401, configured for receiving input from a user and display quotes or results to a user.

The operation control unit 2 further comprises a memory or storage 219 for storing process information of the image generation process of the dual beam device 1 and for storing software instructions, which can be executed by the processing engine 201. The process information of the image generation process with the dual beam device 1 can for example include a library of the effects during the image generation and a list of predetermined material contrasts.

The operation control unit 2 is further connected to an interface unit 231, which is configured to receive further commands or data, for example CAD data, from external devices or a network. The interface unit 231 is further configured to exchange information, for example receive instructions from external devices or provide measurement results to external devices or store a set of training data or a trained machine learning algorithm or plurality of cross section images in external storages.

The operation control unit 2 is connected to dual beam system 1 and configured to receive a plurality of two-dimensional images of a plurality of cross section surfaces. Operation control unit 2 is further configured to receive at least one of a plurality of position vectors or a plurality of measurements of an environmental influence for at least a plurality of representative dwell points used during image acquisition of the plurality of two-dimensional images of a plurality of cross section surfaces.

The operation control unit 2 is configured to determine a three-dimensional (3D) volume image of the inspection volume 160 from the plurality of two-dimensional images of a plurality of cross section surfaces. The operation control unit 2 is configured to determine the three-dimensional (3D) volume image by pixel interpolation from the plurality of nominal, ideal pixel coordinates of the scanning raster 58. During pixel interpolation, the operation control unit 2 is further configured to consider at least one of the plurality of position or displacement vectors or the plurality of measurements of an environmental influence. Thereby, an inspection result of a wafer inspection task is obtained with high precision, even when a measurement task involves longer periods of time with changing conditions. Further details are illustrated below.

The wafer inspection system 1000 is configured to receive user information for execution of a measurement task, for example comprising CAD information of the semiconductor object of interest, the location of the inspection site, or the inspection result. The processing engine 201 is configured to compute and display information via the user display 400 and to receive user input via user interface 401.

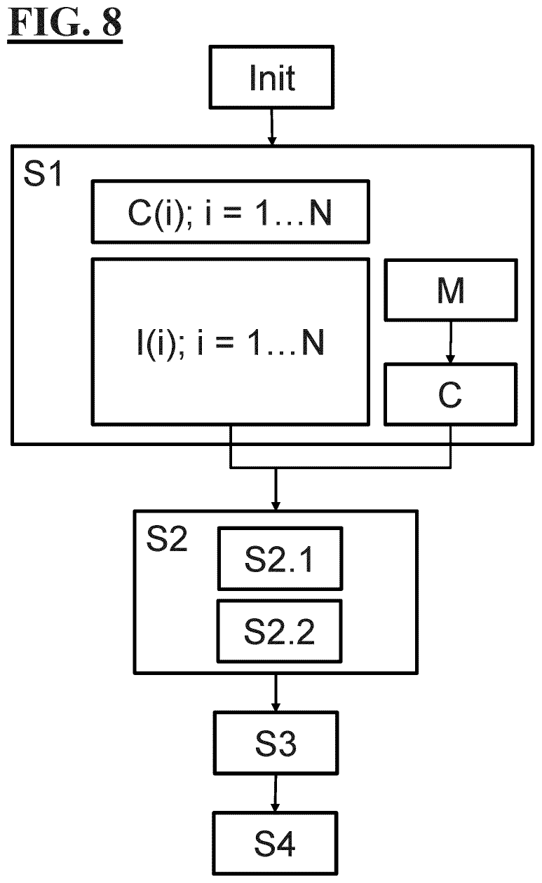

FIG. 8 illustrates an example of a method according to a further embodiment of the disclosure.

In Step Init, an inspection site 6.i is adjusted by wafer stage 155 at the intersection point 43 of the dual beam device 1 and a process for slicing and imaging is determined and initialized. The process can include a local registration of coordinates at the inspection site and the generation of alignment fiducials.

During iterative step S1, a plurality of cross-section surfaces C(i=1 . . . N) is formed into the surface 55 of the wafer 8 by ion-beam milling and a plurality of two-dimensional images I(i=1 . . . N) of the plurality of cross-section surfaces C(i=1 . . . N) is generated by charged particle imaging beam 44 (with i=1 . . . N). At least during image acquisition steps I(i=1 . . . N), monitoring step M is executed for receiving a plurality of monitoring parameters comprising at least one of a plurality of position displacement vectors [dx(p), dy(p)] with sequential pixel number p. The position displacement vectors [dx(p), dy(p)] are obtained by position sensor 21 (see FIG. 7) and correspond to a displacement of the wafer stage 155 during use relative to a reference coordinate of the imaging charged particle beam system 40, for example the optical axis or center axis 42 of the imaging charged particle beam system 40 (see FIG. 1).

In an example, the monitoring parameters are further comprising a plurality of measurement results of an environmental influence E(p) for each pixel number. The two-dimensional images are stored in temporary memory synchronized with the plurality of monitoring parameters. For example, storage of pixel values of image pixels is synchronized with storage of corresponding monitoring parameters, such that each monitoring parameter is associated to at least on representative pixel coordinate.

In an example, iterative slice- and image step S1 further comprises a compensation step C. In compensation step C, at least one monitoring parameter is analyzed and a correction signal is generated. The correction signal is provided by the control unit 19 to elements of the imaging charged particle beam system 40. Examples of corrections signals are a variable offset to a deflection scanner 29 or a variable lens power to electromagnetic objective lens 33. Thereby, slowly varying drifts or larger drifts can be compensated by adjustment of the scanning positions or focus position.

In an example, the monitoring parameters are further analyzed, and a weight function of each image pixel is determined and stored together with a pixel. For example, if the monitoring parameters are strongly varying during a sequence of pixels, a pixel value of an image pixel might be inaccurate due to relative movements and an image pixel might in effect be blurred due to rapid dynamic vibration. Other image pixels might be obtained out of a focal plane of the charged particle imaging beam and an image pixel might in effect be blurred due to defocus. Such image pixels can be flagged by a low weighting factor. Weight factors can be considered in a 3D volume image interpolation in step S2.

During or after milling the N cross section surfaces 53 and acquiring the N two-dimensional cross section image slices, the acquired two-dimensional cross section image slices are provided to Step S2. The number N of cross-sections and cross-section image slices can be at least two, five, thirty, one hundred, or even up to thousand or more.

In Step S2, a 3D volume image is generated from the plurality of N two-dimensional cross section image slices.

The generation comprises a first set of two-dimensional operations S2.1 for each cross-section image slice, comprising at least one of the group of image processing operations including
a computation of drift image pixel coordinates [XD(p), YD(p)] with pixel number p according to the ideal scanning raster coordinates [X(p), Y(p)] and the plurality of position displacement vectors [dx(p), dy(p)] of the wafer stage obtained during monitoring step M:

$$XD ( p ) = X ( p ) + d x ( p )$$

$$YD ( p ) = Y ( p ) + d y ( p )$$

a computation of an additional displacement of image pixel coordinates according to a function F of the measurement results of an environmental influence E(p)

$$XDE ( p ) = XD ( p ) + F ( E ( p ) )$$

$$YDE ( p ) = YD ( p ) + F ( E ( p ) ) .$$

image registration with alignment fiducials or feature based image registration.
image distortion compensation, including magnification adjustment,
image improvement methods, such as noise removal, contrast enhancement, image normalization, and thresholding.
object detection, for example detecting of cross sections of semiconductor objects of interest; examples of object detection methods include template matching or machine learning methods.
a determination of a height map Z(x,y) for each cross-section image slice; and
a determination of the z-coordinate ZDE(p) of each drift compensated lateral pixel coordinate [XDE(p), YDE(p)].

In an example, a measurement result of an environmental influence E(p) is given by a change of an external electromagnetic field, which causes an additional deflection of the charged particle imaging beam 44. In an example, the measurement results of an environmental influence E(p) is given by a thermal drift, which causes a thermal expansion of the metrology frame 25 and causes an additional slowly varying displacement offset of the plurality of position displacement vectors [dx(p), dy(p)], determined by position sensor 21. In an example, the measurement results of an environmental influence E(p) is given by a dynamic excitation of the metrology frame 25 and causes an additional dynamic displacement offset of the plurality of position displacement vectors [dx(p), dy(p)] determined by position sensor 21.

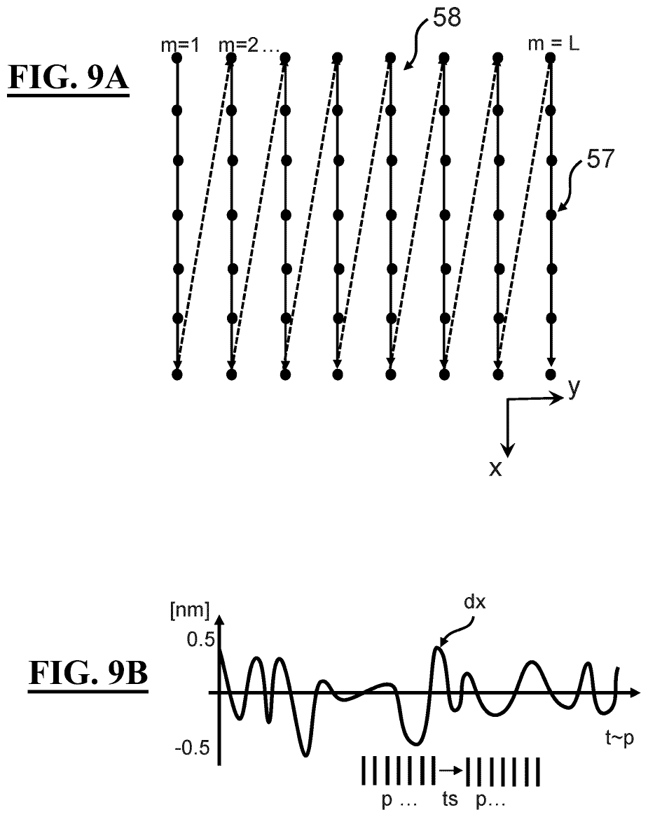

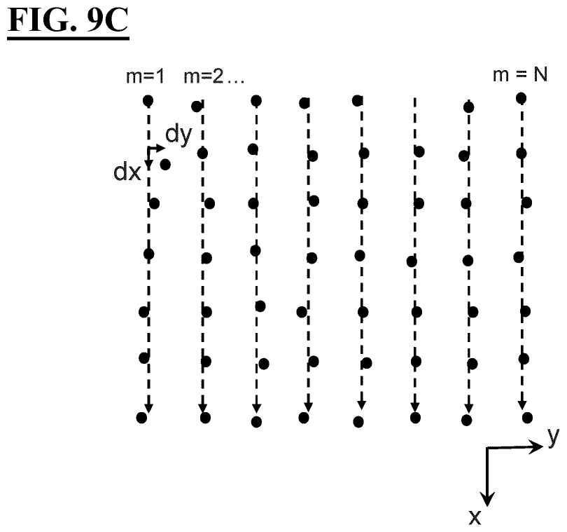

FIGS. 9A-9C illustrate parts of step S2.1 in more detail. FIG. 9A shows an ideal scanning raster 58, comprising a plurality of L scanning lines with ideal dwell points 57. FIG. 9B shows the position displacement vector component dx(t) over scanning time t. With the scanning frequency sf, the position displacement vector component dx(t) can be sampled and the position displacement vector component dx(p) for each ideal dwell point position 57 with pixel sequence number p is extracted. The pixel sequence with indices p is interrupted by fly-back time intervals ts between two subsequent scanning lines m and m+1. FIG. 9C shows the final 2D pixel coordinate map, which correspond to the real coordinates of the dwell points on a cross section surface.

The generation of the 3D volume image further comprises a second set of three-dimensional operations S2.2 for at least a subset of cross section image slice, comprising interpolation of three-dimensional pixel values at coordinates of the regular three-dimensional volume grid of the 3D volume image from the pixel values at drift image pixel coordinates XDE(p), YDE(p) and height coordinates ZDE(p). Different interpolation methods can be applied, with at least one interpolation method selected from a group of interpolation methods including
numerical interpolation,
model-based interpolation, using for example prior knowledge of the semiconductor structure of the wafer from e.g. CAD information. For example, semiconductor features are typically oriented parallel or perpendicular to a wafer surface.
Machine learning based matching interpolation; some semiconductor features have a known shape or geometry, as for example HAR structures. 3D volume pixel values I(q) can be obtained by training of a plurality of interpolation schemes.

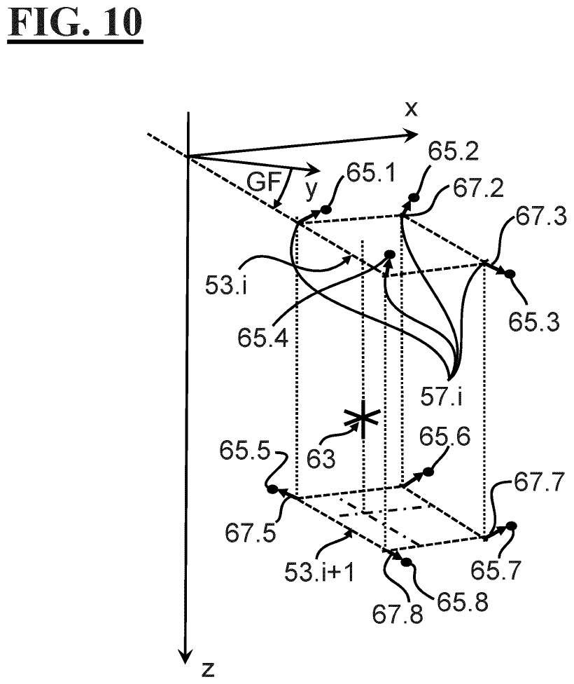

FIG. 10 illustrates an example of the three-dimensional interpolation of the pixel value I(q) of the 3D volume pixel 63 of a regular volume grid with coordinate vector [XV(q), YV(q), ZV(q)]. The pixel value I(q) is interpolated from 8 pixel values, including four pixel values obtained at the four coordinate vectors [XDE(p), YDE(p), ZDE(p)] with p=1, 2, 3, and 4, which correspond to the four real dwell points 65.1 to 65.4 on the ith cross section surface 53.i and four pixel values obtained at the four coordinate vectors [XDE(p), YDE(p), ZDE(p)] with p=5, 6, 7, and 8, which correspond to the four real dwell points 65.5 to 65.8 on the (i+1)th cross section surface 53.i+1.

Numerical interpolation methods can therefore include a trilinear interpolation, a polynomial interpolation, a spline interpolation, or approximation methods such as Runge-Kutta methods. In an example, during pixel interpolation, the weight factors of image pixels determined during step S1 for each image pixel can be considered and pixel values of blurred pixels can be considered with lower weight or discarded at all. For example, a numerical interpolation of a 3D image pixel incorporates an interpolation not only from the next and directly adjacent pixels of two two-dimensional cross-section image slices but incorporates more adjacent pixels from more than two two-dimensional cross-section image slices.

In step S3, object detection and feature extraction, for example including template matching or machine learning algorithms are applied to the three-dimensional volume image. As a final result, for example a position of a target feature, an relative position of at least two target features, a dimension, a shape or an area of a target feature, a deviation from a target feature, an error, or a statistical property of a plurality of target features is determined.

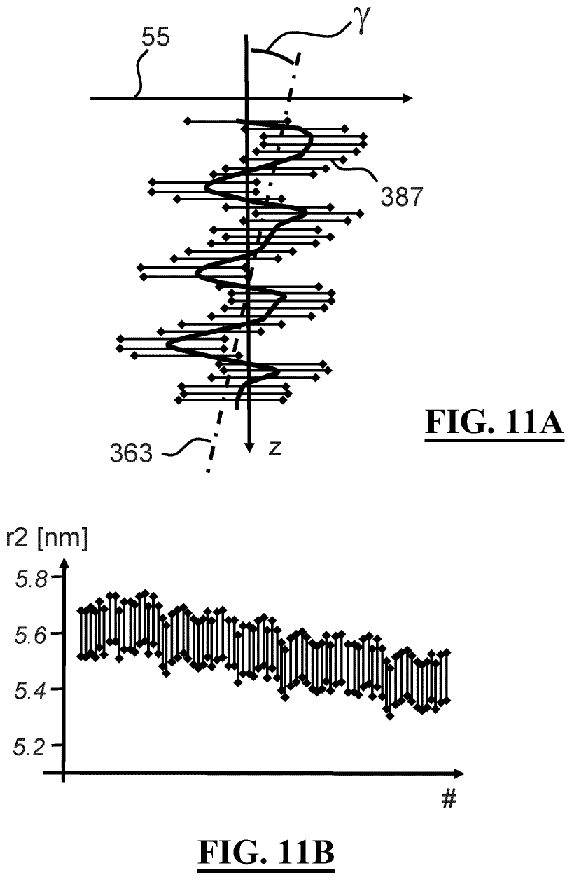

In step S4, the inspection result is processed for display on a user display. The inspection result is further stored in a memory of distributed to external receivers. FIGS. 11A-11B show a typical result of step S4. In FIG. 11A, a trajectory of center coordinates of a HAR channel is shown. Each horizontal line corresponds to one contour of a feature 387, measured at a depth z inside an inspection volume of a wafer. Thereby, a HAR channel can be analyzed and for example an average tilt angle g of average channel trajectory 363 is determined. FIG. 11B illustrates a distribution of measured radius r2 of a plurality of wafer samples. The radius r2 shows a significant drift over wafer samples, which can be an indicator for a process drift during the manufacturing process of wafer. With the method according to the second embodiment, a high accuracy of the measurement result can be achieved, with a measurement error below 1 nm, below 0.5 nm or even less. Small drift errors, which are hard to be compensated by for example a deflection scanner, can be recorded and corrected for during the 3D-pixel interpolation from the plurality of two-dimensional cross section images. Thereby, with a method according to an embodiment, a three-dimensional volume image of higher accuracy is computed from the plurality of two-dimensional cross section images including image drifts. Thereby, with a method according to an embodiment, a three-dimensional volume image of higher accuracy is computed from the plurality of two-dimensional cross section images of lower sampling rate, given by larger milling distance D or larger image sampling in y-direction. With the methods, a measurement time is reduced and a higher accuracy of a three-dimensional volume image is achieved.

With the method of the embodiments and the wafer inspection system 1000 configured to execute a method according to the disclosure, a deterioration of the image quality induced by drift or environmental distributions is reduced.

The method and wafer inspection system 1000 can be used for quantitative metrology, but can also be used for defect detection, process monitoring, defect review, and inspection of integrated circuits within semiconductor wafers.

The disclosure can be described by following clauses:

Clause 1: A method of three-dimensional (3D) volume image acquisition with a dual beam device (1), comprising:
processing, by ion beam milling with a focused ion beam column (50) arranged at an angle GF to a wafer support surface (15), a plurality of cross-section surfaces (C(i=1 . . . N), 52, 53) in a wafer (8),
acquiring, by a charge particle beam imaging system (40) arranged at an angle GE to a normal to the wafer support surface (15), a plurality of two-dimensional cross-section images (I(i=1 . . . N), 311) with a predefined scanning raster (58), comprising a two-dimensional cross-section image (311) for each of the cross-section surfaces (C(i=1 . . . N), 52, 53),
obtaining, during acquiring of each of the two-dimensional cross-section images (I(i=1 . . . N), 311), a plurality of displacement vectors [dx(p), dy(p)] (67) between a wafer stage (155) and the charge particle beam imaging system (40),
determining a three-dimensional (3D) volume image from the plurality of two-dimensional cross-section images (I(i=1 . . . N), 311) by 3D-pixel interpolation from the plurality two-dimensional images (I(i=1 . . . N), 311) with pixel locations of the predefined scanning raster (58) displaced by the plurality of displacement vectors [dx(p), dy(p)] (67).

Clause 2: The method of clause 1, further comprising storing the plurality of displacement vectors [dx(p), dy(p)] (67) synchronized with the storing of pixel values of image pixels of each of the two-dimensional cross-section images (I(i=1 . . . N), 311).

Clause 3: The method of clause 1 or 2, further comprising
analyzing the plurality of displacement vectors (67),
generating a correction signal, and
providing the correction signal to a compensation element of the imaging charged particle beam system (40).

Clause 4: The method according to any of the clauses 1 to 3, comprising
computing of drift image pixel coordinates [XD(p), YD(p)] according to pixel locations [X(p), Y(p)] of the predefined scanning raster (58) displaced by the plurality of displacement vectors [dx(p), dy(p)] (67),
determination of a height map Z(x,y) for each cross-section image (I(i=1 . . . N), 311); and
determining of z-coordinates ZD(p) of each drift compensated lateral pixel coordinate [XD(p), YD(p)].

Clause 5: The method according to any of the clause 4, comprising determining the three-dimensional (3D) volume image by 3D-pixel interpolation from the drift image pixel coordinates [XD(p), YD(p), ZD(p)] of the plurality two-dimensional images (I(i=1 . . . N), 311).

Clause 6: The method according to any of the clauses 1 to 5, wherein the 3D-pixel interpolation method is selected from a group of interpolation methods including numerical interpolation, model-based interpolation, and feature matching interpolation using CAD data.

Clause 7: The method according to any of the clauses 1 to 6, comprising
obtaining, during acquiring of each of the two-dimensional cross-section images (I(i=1 . . . N), 311), a plurality of measurement results of an environmental influence E(p).

Clause 8: The method according to clause 7, further comprising storing of the plurality of measurement results of an environmental influence E(p) synchronized with the storing of pixel values of image pixels of each of the two-dimensional cross-section images (I(i=1 . . . N), 311).

Clause 9: The method according to clause 7 or 8, further comprising computing of an additional displacement of pixel locations [X(p), Y(p)] of the predefined scanning raster (58) according to a function F of an environmental influence E(p).

Clause 10: The method according to any of the clauses 1 to 9, further comprising an image registration of each of the two-dimensional cross-section images (I(i=1 . . . N), 311) with alignment fiducials or a feature-based image registration.

Clause 11: The method according to any of the clauses 1 to 10, further comprising at least one image improvement method selected from a group of methods including an image distortion compensation, a magnification adjustment, a noise removal, a contrast enhancement, an image normalization, and a thresholding.

Clause 12: The method according to any of the clauses 1 to 11, further comprising an object detection selected from a group of object detection methods including template matching, contour extraction and machine learning object detectors.

Clause 13: A dual beam system (1), comprising
a wafer stage (155) for holding a wafer (8) on a wafer support surface (15),
a focused ion beam column (50) at a first angle GF to the wafer support surface (15),
a charged particle beam imaging system (40) mounted on a rigid support frame (25) at a second angle GE to a normal to the wafer support surface (15),
a high precision sensor (21) for measuring during use a plurality of relative position vectors between the wafer stage (155) and the rigid support frame (25),
a control unit (19) with a processing logic and at least one memory for storing a set of software instructions and for at least temporally storing image pixel values obtained by an image sensor (17.1, 17.2) according to the pixel locations of a selected scanning raster (58), wherein the processing logic is configured to execute the set of software instructions to cause the dual beam system (1) to perform a method of any of the clauses 1 to 12.

Clause 14: The dual beam system (1) according to clause 13, wherein the angle GF is between 10° and 60° and the angle GE is between 0° and 60°.

Clause 15: The dual beam system (1) according to clause 13 wherein the angle GE=0°.

Clause 16: The dual beam system (1) according to clause 13 or 14, wherein the focused ion beam column (50) and the charged particle beam imaging system (40) are arranged relative to each other at an angle GFE, wherein the angle GFE=90°.

Clause 17: A dual beam system (1), comprising
a wafer stage (155) for holding a wafer (8) on a wafer support surface (15),
a focused ion beam column (50) at a first angle GF to the wafer support surface (15),
a charged particle beam imaging system (40) mounted on a rigid support frame (25) at a second angle GE to a normal to the wafer support surface (15), for obtaining a plurality of cross-section image slices (I(i=1 . . . N), 311),
a control unit (19) with a memory and logic to control an operation of the dual beam system (1) and to temporally store image pixel values obtained by an image sensor (17.1, 17.2) according to the pixel locations of a selected scanning raster (58),
a high precision sensor (21), connected to the control unit (19), for measuring during use a plurality of displacement vectors [dx(p), dy(p)] (67) between the wafer stage (155) and the rigid support frame (25), wherein the control unit (2, 19) is configured to receive and store the plurality of displacement vectors [dx(p), dy(p)] (67) in correspondence with the pixel locations of the selected scanning raster (58) and configured to determine a three-dimensional (3D) volume image by 3D-pixel interpolation.

Clause 18: The dual beam system (1) of clause 17, wherein the control unit (2, 19) is configured to
computing of drift image pixel coordinates [XD(p), YD(p)] according to pixel locations [X(p), Y(p)] of the predefined scanning raster (58) displaced by the plurality of displacement vectors [dx(p), dy(p)] (67)
determining a height map Z(x,y) for each of a plurality of cross-section image slice (I(i=1 . . . N), 311) and z-coordinates ZD(p) of each drift compensated lateral pixel coordinate [XD(p), YD(p)], and
determine the three-dimensional (3D) volume image by 3D-pixel interpolation from the drift image pixel coordinates [XD(p), YD(p), ZD(p)] of plurality two-dimensional images (311).

Clause 19: A method of three-dimensional (3D) volume image acquisition with a dual beam device (1), comprising:
processing, by ion beam milling with a focused ion beam column (50) arranged at a slanted angle GF between 10° and 60° to a wafer support surface (15), a plurality of cross-section surfaces (C(i=1 . . . N), 52, 53) in a wafer (8), each pair of cross-section surfaces (C(i=1 . . . N), 52, 53) having a milling distance D,
acquiring, by a charge particle beam imaging system (40) arranged at an angle GE to a normal to the wafer support surface (15), a plurality of two-dimensional cross-section images (I(i=1 . . . N), 311) with a predefined scanning raster (58) with a sampling raster of dy<D/sin (GF) or dy>D/sin (GF) in a y-direction, the plurality of two-dimensional cross-section images (I(i=1 . . . N), 311) comprising a two-dimensional cross-section image (311) of each of the cross-section surfaces (C(i=1 . . . N), 52, 53),
determine a three-dimensional (3D) volume image from the plurality of two-dimensional cross-section images (I(i=1 . . . N), 311) by pixel interpolation from the plurality two-dimensional images (I(i=1 . . . N), 311).

Clause 20: The method according to clause 19, comprising
determination of a height map Z(x,y) for each cross-section image slice (I(i=1 . . . N), 311); and
determining the three-dimensional (3D) volume image by 3D-pixel interpolation from the image pixel coordinates [X(p), Y(p), Z(X(p), Y(p)] of the plurality two-dimensional images (I(i=1 . . . N), 311).

Clause 21: The method according to clause 20, wherein at least one 3D-pixel interpolation method is including a model-based interpolation or feature matching interpolation using CAD data.

Clause 22: The method according to any of the clauses 19 to 21, comprising obtaining, during acquiring of each of the two-dimensional cross-section images (I(i=1 . . . N), 311), a plurality of displacement vectors [dx(p), dy(p)] (67) between a wafer stage (155) and the charge particle beam imaging system (40).

Clause 23: The method of clause 22, further comprising storing the plurality of displacement vectors [dx(p), dy(p)] (67) synchronized with the storing of pixel values of image pixels of each of the two-dimensional cross-section images (I(i=1 . . . N), 311).

Clause 24: The method of clause 22 or 23, further comprising
computing of drift image pixel coordinates [XD(p), YD(p)] according to pixel locations [X(p), Y(p)] of the predefined scanning raster (58) displaced by the plurality of displacement vectors [dx(p), dy(p)] (67),
determination of a height map Z(x,y) for each cross-section image (I(i=1 . . . N), 311),
determining of z-coordinates ZD(p) of each drift compensated lateral pixel coordinate [XD(p), YD(p)], and
determining the three-dimensional (3D) volume image by 3D-pixel interpolation from the drift image pixel coordinates [XD(p), YD(p), ZD(p)] of the plurality of two-dimensional images (I(i=1 . . . N), 311).

The disclosure described by examples and embodiments is however not limited to the clauses but can be implemented by those skilled in the art by various combinations or modifications.

A list of reference numbers is provided:
1 Dual Beam system
2 Operation Control Unit
6 inspection site
8 wafer
15 wafer support table
16 stage control unit
17 Electron detector
19 Control processor Unit
21 Position Sensor
23 Environment Sensor
25 Metrology Frame
27 position measurement
29 scanning deflector
31 electron source
33 objective lens
40 charged particle beam (CPB) imaging system
42 Optical Axis of imaging system
43 Intersection point
44 Imaging charged particle beam
48 Fib Optical Axis
50 FIB column
51 focused ion beam
52 cross section surface
53 cross section surface
55 wafer top surface
57 ideal dwell point
58 scanning raster
59 Scanning lines and columns
61 virtual image slices
63 3D volume pixel
65 real dwell points
67 displacement vector
155 wafer stage
160 inspection volume
201 processing engine
203 memory
205 User interface
219 memory
231 Interface unit
307 measured cross section image of HAR structure
311 cross section image slice
313 word lines
315 edge with surface
363 average HAR channel trajectory
400 user interface display
401 user command devices
1000 Wafer inspection system

What is claimed is:

1. A method, comprising:
ion beam milling a wafer with a focused ion beam column to provide a plurality of cross-section surfaces in the wafer;
for each of the plurality of cross-section surfaces in the wafer, using a charged particle beam imaging system to acquire a two-dimensional cross-section image with a predefined scanning raster;
during the acquisition of each of the two-dimensional cross-section images, obtaining a plurality of displacement vectors between a wafer stage and the charged particle beam imaging system; and
determining a three-dimensional (3D) volume image from the plurality of two-dimensional cross-section images by 3D-pixel interpolation from the plurality two-dimensional cross-section images with pixel locations of the predefined scanning raster displaced by the plurality of displacement vectors.

2. The method of claim 1, further comprising synchronizedly storing of the plurality of displacement vectors and pixel values of image pixels of each of the two-dimensional cross-section images.

3. The method of claim 1, further comprising:
analyzing the plurality of displacement vectors;
generating a correction signal; and
providing the correction signal to a compensation element of the charged particle beam imaging system.

4. The method of claim 1, comprising:
computing drift image pixel coordinates according to pixel locations of the predefined scanning raster displaced by the plurality of displacement vectors;
for each cross-section image, determining a height map; and
each drift compensated lateral pixel coordinate, determining z-coordinates of the drift compensated lateral pixel coordinate.

5. The method of claim 4, comprising determining the 3D volume image by 3D-pixel interpolation from the drift image pixel coordinates of the plurality two-dimensional images.

6. The method of claim 1, wherein the 3D-pixel interpolation method comprises a method selected from the group consisting of numerical interpolation, model-based interpolation, and feature matching interpolation using CAD data.

7. The method of claim 1, further comprising obtaining, during acquisition of each of the two-dimensional cross-section images, a plurality of measurement results of an environmental influence.

8. The method of claim 7, further comprising storing the plurality of measurement results of the environmental influence synchronized with the storing of pixel values of image pixels of each of the two-dimensional cross-section images.

9. The method of claim 7, further comprising computing an additional displacement of pixel locations of the predefined scanning raster according to a function of the environmental influence.

10. The method of claim 1, further comprising, for each of the two-dimensional cross-section images, registering the image with alignment fiducials or using a feature-based image registration.

11. The method of claim 1, further comprising using at least one image improvement method selected from the group consisting of an image distortion compensation, a magnification adjustment, a noise removal, a contrast enhancement, an image normalization, and a thresholding.

12. The method of claim 1, further comprising detecting an object using at least one method selected from the group consisting of template matching, contour extraction and machine learning object detectors.

13. One or more machine-readable hardware storage devices comprising instructions that are executable by one or more processing devices to perform operations comprising the method of claim 1.

14. A system, comprising:
one or more processing devices; and
one or more machine-readable hardware storage devices comprising instructions that are executable by one or more processing devices to perform operations comprising the method of claim 1.

15. The system of claim 14, further comprising:
a dual beam system, comprising:
a wafer stage configured to hold the wafer on a wafer support surface;
a focused ion beam column;
a charged particle beam imaging system;
a rigid support frame supporting the charged particle beam imaging system; and
a high precision sensor configured to measure a plurality of relative position vectors between the wafer stage and the rigid support frame.

16. The system of claim 15, wherein the focused ion beam is at an angle between 10° and 60° relative to the wafer support surface, and the charged particle beam imaging system is at an angle between 0° and 60° relative to wafer support surface.

17. The system of claim 15, wherein the focused ion beam is at an angle between 10° and 60° relative to the wafer support surface, and the charged particle beam imaging system is at an angle of 0° relative to wafer support surface °.

18. The system of claim 15, wherein the focused ion beam column and the charged particle beam imaging system are disposed relative to each other at an angle of 90°.

19. A dual beam system, comprising:
a wafer stage configured to hold the wafer on a wafer support surface;
a focused ion beam column;
a charged particle beam imaging system;
a rigid support frame supporting the charged particle beam imaging system;
a high precision sensor configured to measure a plurality of displacement vectors between the wafer stage and the rigid support frame; and
a control unit configure to:
control the dual beam system and to temporally store image pixel values obtained by an image sensor according to the pixel locations of a selected scanning raster;
receive and store the plurality of displacement vectors in correspondence with the pixel locations of the selected scanning raster; and
determine a three-dimensional (3D) volume image by 3D-pixel interpolation.

20. The dual beam system of claim 19, wherein the control unit is configured to:
compute drift image pixel coordinates according to pixel locations of the predefined scanning raster displaced by the plurality of displacement vectors;
determine a height map for each of a plurality of cross-section image slices and z-coordinates of each drift compensated lateral pixel coordinate; and
determine the 3D volume image by 3D-pixel interpolation from the drift image pixel coordinates of plurality two-dimensional images.
